(19) United States
(12) Patent Application Publication
(10) Pub. No.: US 2003/0062914 A1
(43) Pub. Date: Apr. 3, 2003

(54) Surface mating compliant contact assembly with fixed signal path length

(76) Inventor: Cosmin Iorga, Oak Park, CA (US)

Correspondence Address: Legal Department, Teradyne, Inc., 321 Harrison Avenue, Boston, MA, 02118, US

(21) Appl. No.: 09/967,682

(22) Filed: Sep. 28, 2001

(51) Int. Cl. G01R 31/02

(52) U.S. Cl. 324/761

(57) ABSTRACT

A surface mating coaxial contact assembly for use in a cortact module is disclosed. The contact module is adapted for engaging the surface of a substantially planar circuit board. The surface mating coaxial contact assembly includes a cylindrical electrically conductive coaxial contact of a fixed length and having a center conductor path and a shield conductor path. The center conductor path and the shield conductor path terminate in a coplanar tip assembly. A biasing assembly is coupled to the contact and includes a catch adapted for engaging the contact module. The biasing assembly allows for axial displacement of the contact with respect to the catch without altering the length of the contact.

### FIELD OF THE INVENTION

The invention relates generally to automatic test equipment for testing semiconductor devices, and more particularly a tester interface for electrically coupling a semiconductor tester to a device-interface-board.

### BACKGROUND OF THE INVENTION

Automatic test equipment, commonly referred to as a semiconductor tester, provides a critical role in the manufacture of semiconductor devices. The equipment enables the functional test of each device both at the wafer stage and the packaged-device stage. By verifying device operability and performance on a mass-production scale, device manufacturers are able to command premium prices for quality products.

One conventional type of automatic test system includes a computerdriven test controller and a test head connected electrically to the controller by a heavy-duty multi-cable. A manipulator mechanically carries the test head. The test head generally includes a plurality of channel cards that mount the pin electronics necessary to generate the test signals or patterns to each I/O pin or contact of one or more devices-under-test (DUTs).

One of the primary purposes of the test head is to place the channel card pin electronics as close to the DUT as practicable to minimize the distance that signals must propagate therebetween. The length and construction of the signal path interfacing the test head to the DUT, commonly referred to as a tester interface, directly affects signal delays and signal losses. Consequently, tester interface schemes that interconnect the pin electronics to the DUT play an important role in the achievable accuracy of a semiconductor tester.

With reference to FIG. 1, one conventional high performance tester interface includes a connector module 12 that houses the terminations for a plurality of coaxial cables 14. The terminations, commonly referred to as pogo pins, are adapted to engage a multi-layered circuit board, or device-interface-board (DIB, not shown). Referring more particularly to FIG. 2, each pogo pin includes a signal conductor 20 coupled to a compliant spring 22, while each cable shield 24 couples to the contact barrel 26. The barrel connects to the module 12 in an interference fit as a ground connection. A ground pogo pin assembly 18 connects to the signal pogo barrel through the barrel-module ground connection to continue the ground path through to the DIB. Typically, a plurality of ground paths surround each signal path to minimize high frequency interference.

While the conventional pogo-based tester interface described above works well for its intended applications, one of the drawbacks is a practical bandwidth barrier of around 1 GHz. At such high frequencies, the signal path characteristics emulate transmission lines, generally requiring matched 50-ohm environments. Deviations from the 50-ohms often cause signal degradations that lead to timing inaccuracies and the like. Inaccuracy in the tester may improperly fail devices that perform near threshold levels.

Conventional interface signal path constructions, such as that described above, generally employ numerous connections and discontinuities that affect the characteristic impedance. One of the discontinuities involves inductive effects generated as the coils of the spring 22 (FIG. 2) touch the interior of the contact receptacle 28 during compression and expansion. Inductance tends to inhibit high speed signal propagation.

Moreover, another drawback with conventional standard and coaxial pogo pins involves how the compliance is provided. Compliance is a desirable function for arrays of contacts due to the non-planarity imperfections associated with the surface of the multi-layered device-interface-board. With several thousand pins touching down on a relatively small area, compliance for each pin overcomes any surface imperfections, allowing all of the pins to successfully contact the board. Typically, the compliance for each pin is provided by the contact spring 22 (FIG. 2) disposed in the signal path (or ground path, or both) of the contact assembly. When compressed, the length of the contact actually decreases, consequently decreasing the length of the signal path.

Knowing the length of the signal path is an important factor in maximizing tester accuracy. This is because of the signal delay associated even with very short paths of a few inches or less. Calibration often solves this problem to a certain degree.

Typically, calibration procedures are carried out on a customized calibration board. During calibration, the path lengths through the coaxial cables and pogo pins are measured by a time-domain-reflectometry (TDIR) method, and the resulting delays determined. After calibration, the calibration DIB is replaced by the production DIB.

Unfortunately, the production DIB and the calibration DIB do not have exactly the same planarity characteristics. As a result, many of the pogo pins that measured a length L during calibration might have a different length L+ΔL during production testing. While timing inaccuracies associated with the different DIBs are relatively minor for accuracy requirements of 500 picoseconds or more, high-speed testers may require total system inaccuracies of no greater than 25 picoseconds. It has been estimated that path length deviations on the order of 10 to 20 mils, caused by the differences in planarity between calibration and production DIBs, can cause timing calibration inaccuracies of up to 3 picoseconds. This is unacceptable for a tester trying to achieve 25 Ps accuracy.

Thus, the need exists for a pogo pin-based interface scheme that maintains signal integrity and minimizes timing inaccuracies. The present invention satisfies these needs.

### SUMMARY OF THE INVENTION

The contact assembly of the present invention provides high accuracy semiconductor device testing for high bandwidth applications while maximizing pin density and substantially improving tester interface reliability. This correspondingly results in lower test costs and higher tester performance.

To realize the foregoing advantages, the invention in one form comprises a surface mating coaxial contact assembly for use in a contact module. The contact module is adapted for engaging the surface of a substantially planar circuit board. The surface mating coaxial contact assembly includes a cylindrical electrically conductive coaxial contact of a fixed length and having a center conductor path and a shield conductor path. The center conductor path and the shield conductor path terminate in a coplanar tip assembly. A biasing assembly is coupled to the contact and includes a catch adapted for engaging the contact module. The biasing assembly allows for axial displacement of the contact with respect to the catch without altering the length of the contact.

In another form, the invention comprises a contact module assembly for interfacing a plurality of tester channels to a device-interface-board. The harness assembly includes a plurality of coaxial cables, each terminating in a surface mating coaxial contact assembly. Each surface mating coaxial contact assembly including a cylindrical electrically conductive coaxial contact of a fixed length and having a center conductor path and a shield conductor path. The center conductor path and the shield conductor path terminate in a coplanar tip assembly. A biasing assembly is coupled to the contact and includes a catch adapted for engaging the contact module. A housing formed with a plurality of receptacles receives and secures the contact assemblies and is formed with a retainer for engaging the biasing assembly catch.

In yet another form, the invention comprises a method of interfacing a plurality of tester channels to a device-interface-board. The method includes the steps of transmitting the tester signals along respective transmission lines to respective surface mounting coaxial contacts, the transmission lines and contacts defining signal paths of predetermined lengths; engaging the coaxial contacts against corresponding pads on the device-interface-board; and biasing the contacts against the corresponding pads without changing the predetermined lengths of the signal paths.

Other features and advantages of the present invention will be apparent from the following detailed description when read in conjunction with the accompanying drawings.

### BRIEF DESCRIPTION OF THE DRAWINGS

The invention will be better understood by reference to the following more detailed description and accompanying drawings in which

FIG. 1 is a partial perspective view of a conventional interface module;

FIG. 2 is a partial cross-sectional view of a conventional signal-ground pogo pin pair along line 2-2 of FIG. 1;

FIG. 3 is a contact module for use with the contact assembly of the present invention;

FIG. 4 is a partial axial cross-sectional view of a surface mount coaxial contact assembly for use with the contact module of FIG. 3; and

FIG. 5 is a partial cross-sectional view of a surface mount coaxial contact assembly according to a second form of the present invention.

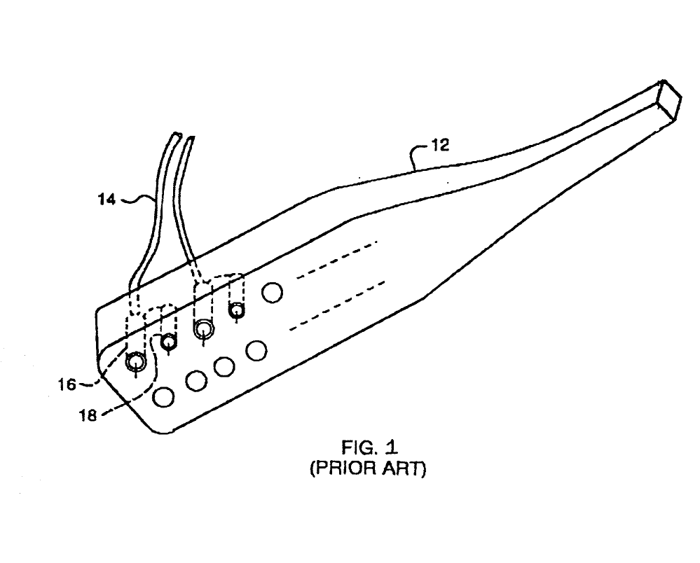

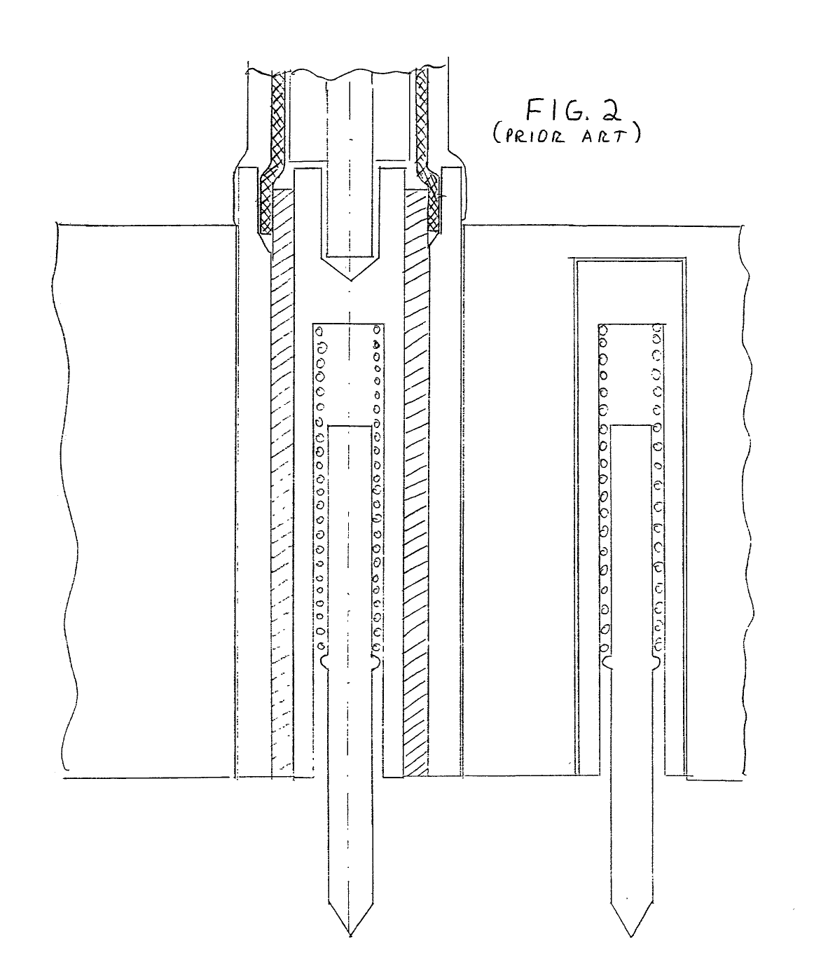

### DETAILED DESCRIPTION OF THE INVENTION

Compliant contact assemblies provide an important interfacing function in modem ATE systems. Ensuring reliable and high fidelity signal path connections between tester pin electronics and the device-under-test helps to maximize device yields for semiconductor manufacturers. The present invention maximizes tester accuracy by providing a compliant contact assembly that makes reliable connections and minimizes characteristic impedance discontinuities while maintaining a fixed signal path length.

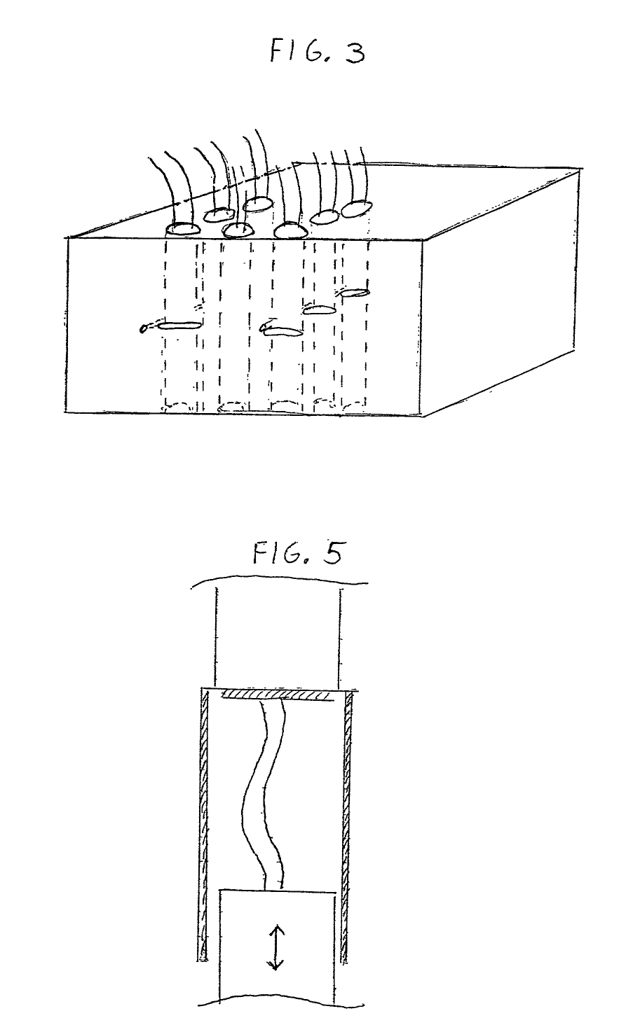

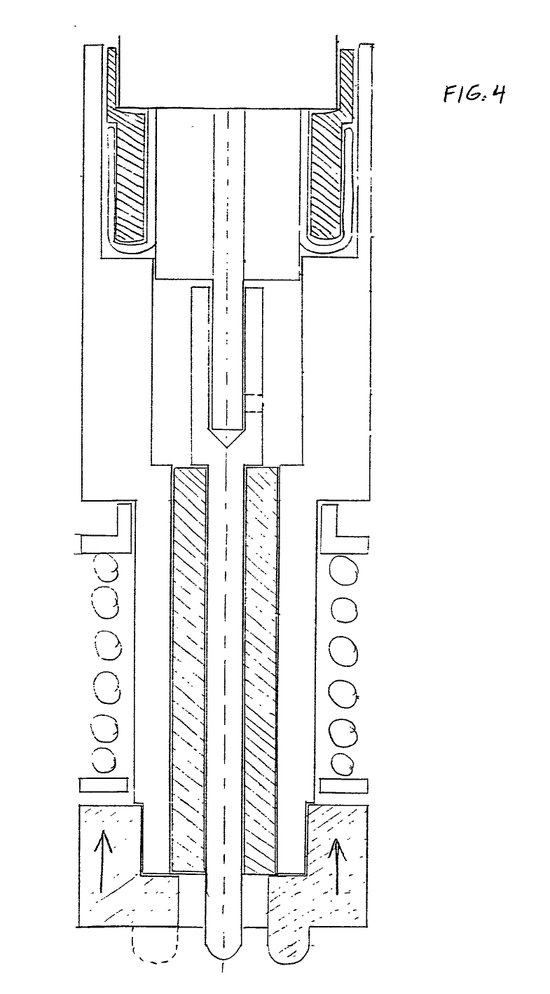

Referring to FIGS. 3 and 4, the compliant contact assembly of the present invention, generally designated 40, is of the surface mount type to electrically couple a tester signal channel from a testhead channel card to a device-interface-board (DIB) (included as part of a handling apparatus such as a prober or a handler). In practice, thousands of compliant contacts are disposed in a contact module 30 (FIG. 3) and utilized to transmit thousands of channels' worth of tester signals from multiple channel cards to the DUT pins.

Further referring to FIG. 3, the contact module assembly 30 includes a plurality of coaxial cables 32 having respective center conductors 33 (FIG. 4) and shields 35 (FIG. 4) that serve as signal transmission lines for high-speed tester signals propagating between the tester pin-electronics (not shown) and the device-under-test (DUT, not shown). The testhead end of each cable terminates in a high density coaxial connector (not shown) that mates to a testhead backplane assembly (not shown). The backplane assembly interfaces to the testhead channel cards (not shown). This general structure is conventional and well known in the art.

With continued reference to FIG. 3, the distal ends of the bundled group of cables 32 terminate in respective coaxial surface mount contact assemblies 40 within a metallic housing in a high-pitch relationship to form a high-density harness/connector structure. The housing comprises a rectangular-shaped block formed with an array of spaced-apart bores 34 that each form a receptacle for receiving each contact assembly 40. Transverse bores 36 formed in the block along each row of pins provide ingress and egress of a retainer 3 8 that engages each row of contacts for maintaining the contacts in the receptacles during calibration and operation.

Referring more particularly now to FIG. 4, each surface mount contact assembly 40 includes a bushing 42 that press-fits around the end of the coaxial cable 32. The bushing is formed with an annular channel 44 for folding back the cable shield (or braid) 35. A narrow contact tip 46 caps the end of the cable center conductor 33 and is coaxially fit with a foam dielectric insert 48. A hollow contact barrel 50 surrounds the entire assembly and is formed at one end with an annular flange 52 for engaging the folded braid 33. The flange, in turn, is complementally formed to nest within the receptacle (bores, FIG. 3) and provide a reliable ground connection with the housing 30. The other end of the barrel includes an opening 54 for passing the contact tip therethrough.

The barrel further includes a reduced-in-diameter portion formed externally to mount a biasing assembly 60. The biasing assembly includes respective first and second washers 62 and 64 that bound the ends of a compressible spring 66. The first washer is formed with a hat-shape having an axial engagement flange 68 that forms a catch. The catch is sized to complementally engage the retainer 38 (FIG. 3).

Mounted at the tip of the barrel 50 is a ground contact tip assembly comprising an annular collar 56 formed with a pair of spaced-apart ground contact tips 57 and 58. The ground contact tips are spaced apart radially from the center conductor tip in such a manner as to form an equilateral triangle, and disposed coplanar with the center tip to effect a simultaneous touchdown when engaged upon the DIB. This three-point construction ensures a stable touchdown upon the DIB, much like a three-legged chair.

The dimensional parameters for each signal path are optimized to provide the closest 50 ohm match as possible to minimize any degradation to propagating signals. The precise sizing necessary to accomplish this will vary with the application desired. Nevertheless, such design parameters are well known to those skilled in the art.

When assembled in the contact module 30, each contact assembly is held in place within the receptacle by the retainer as it engages the catch 68. Consequently, for each contact, the compliance reference point, or “stop”, is the retainer, and not the barrel of the contact assembly. This allows the contact barrel to move axially within the receptacle, as necessary, to effect a reliable connection on the DIB during touchdown. More importantly, this allows the signal path to remain at a fixed unchanging length, and moves the compliant element out of the electrical path. As a result, any characteristic impedance discontinuity that might arise from current flowing through the spring is eliminated.

Prior to operation, the interface is coupled to a calibration DIB (not shown), such that all of the pins touch down on the DIB, and compress as neccessary in order to effect a reliable connection. The signal path lengths (from the tester pin electronics to the contact tips) are then measured using a TDR process. This procedure determines the relative signal delays between the tester pin electronics and the DIB. The delays are then calibrated out of the system to provide maximum timing signal accuracy. Following calibration, the calibration DIB is replaced by the production DIB.

In operation, the semiconductor tester channel cards generate and receive high frequency signals for application to and capture from one or more DUTs. Signals for respective channels are transmitted at gigahertz frequencies through the backplane assemblies and along respective interface module signal cables and ground cables adjacent the signal cables. Each tester channel signal is routed along the coaxial cable center conductor 33 and propagates through the contact assembly tip for subsequent connection to the corresponding underlying probecard contact. Because the compliance function for each pin is carried out by the biasing assembly 60 independently from the cable center conductor 33 and shield 35, the signal path length during production testing remains unchanged from that measured during calibration. Thus, signal performance and accuracy is maintained at an optimal level.

Referring now to FIG. 5, a second embodiment of the present invention provides a minor refinement to the contact assembly 40 by improving the capability of the contact complying within the receptacle. In certain applications, the cable density is of such a degree as to inhibit axial displacement of the individual contacts within the receptacle. The variation provided to solve this problem includes adding a short section (approximately 0.5 inch) of narrow (approx. 0.01 inch diameter) flexible coaxial cable 80 between the main coax cable 33 and the contact assembly barrel 50. A cylindrical ferrule 82 surrounds the interconnections. The narrow section of cable itself provides a small amount of compliance to absorb any upward displacement of the contact within the receptacle. While this introduces two additional connection points in the cable assembly, the short length minimizes any undesirable effects on signal quality.

Those skilled in the art will appreciate the many benefits and advantages afforded by the present invention. Of particular importance is fixed signal path length for each contact achievable by isolating the compliance function from the contact signal transmission function. Further, the invention achieves a superior characteristic impedance by eliminating the discontinuities associated with electric current flowing through the compliant spring. Moreover, by providing a three-point tip interface, reliable and stable contacts are made during touchdown, maximizing signal integrity.

While the invention has been particularly shown and described with reference to the preferred embodiments thereof, it will be understood by those skilled in the art that various changes in form and detail may be made therein without departing from the spirit and scope of the invention.

What is claimed is:

1. A surface mating coaxial contact assembly for use in a contact module, the contact module adapted for engaging the surface of a substantially planar circuit board, the surface mating coaxial contact assembly including:
a cylindrical electrically conductive coaxial contact of a fixed length and having a center conductor path and a shield conductor path, the center conductor path and the shield conductor path terminating in a coplanar tip assembly; and
a biasing assembly coupled to the contact and having a catch adapted for engaging the contact module;
wherein the biasing assembly allows for axial displacement of the contact with respect to the seat.

2. A surface mating coaxial contact assembly according to claim 1 wherein:
the coplanar tip assembly includes a signal conductor tip and a pair of ground conductor tips, the signal conductor tip and ground tips cooperating to form a three-point interface.

3. A surface mating coaxial contact assembly according to claim 1 wherein:
the biasing assembly includes a spring slidably received coaxially around the exterior of the contact, and a pair of washers formed with apertures for receiving the contact and axially disposed at each end of the spring along the contact, one of the washers including a flange defining the catch.

4. A contact module assembly for interfacing a plurality of tester channels to a device-interface-board, the harness assembly including:
a plurality of coaxial cables, the coaxial cables each terminating in a surface mating coaxial contact assembly, each surface mating coaxial contact assembly including
a cylindrical electrically conductive coaxial contact of a fixed length and having a center conductor path and a shield conductor path, the center conductor path and the shield conductor path terminating in a coplanar tip assembly, and
a biasing assembly coupled to the contact and having a catch adapted for engaging the contact module; and
a housing formed with a plurality of receptacles for receiving and securing the contact assemblies, the housing formed with a retainer for engaging the biasing assembly catch.

5. A surface mating coaxial contact assembly according to claim 4 wherein:
the coplanar tip assembly includes a signal conductor tip and a pair of ground conductor tips, the signal conductor tip and ground tips cooperating to form a three-point interface.

6. A surface mating coaxial contact assembly according to claim 4 wherein:
the biasing assembly includes a spring slidably received coaxially around the exterior of the contact, and a pair of washers formed with apertures for receiving the contact and axially disposed at each end of the spring along the contact, one of the washers including a flange defining the catch.

7. A surface mating coaxial contact assembly for use in a contact module, the contact module adapted for engaging the surface of a substantially planar circuit board, the surface mating coaxial contact assembly including:
coaxial contact means of a fixed length and having a center conductor path and a shield conductor path, the center conductor path and the shield conductor path terminating in a coplanar tip assembly; and
means for biasing the contact against the circuit board without altering the signal path length.

8. A method of interfacing a plurality of tester channels to a device-interface-board, the method including the steps of:
transmitting the tester signals along respective transmission lines to respective surface mounting coaxial contacts, the transmission lines and contacts defining signal paths of predetermined lengths;
engaging the coaxial contacts against corresponding pads on the device-interface-board; and
biasing the contacts against the corresponding pads without changing the predetermined lengths of the signal paths.
